(19) United States
(12) Patent Application Publication
(10) Pub. No.: US 2005/0014342 A1
(43) Pub. Date: Jan. 20, 2005

(54) Small, scalable resistive element and method of manufacturing

(75) Inventors: Daniel Worledge, Poughquag, NY (US); Ulrich Klostermann, Fishkill, NY (US); Wolfgang Raberg, Fishkill, NY (US); Stephen L. Brown, Carmel, NY (US)

Correspondence Address: MICHAEL J. BUCHENHORNER, ESQ;HOLLAND & KNIGHT, 701 BRICKELL AVENUE, MIAMI, FL, 33131, US

(73) Assignee: International Business Machines Corporation, Yorktown Heights, NY (US)

(21) Appl. No.: 10/622,422

(22) Filed: Jul. 18, 2003

(51) Int. Cl. H01L 21/8234; H01L 21/8244

(52) U.S. Cl. 438/384

(57) ABSTRACT

An improved scalable, resistive element for use in a semiconductor device that can be produced with a small feature size and precise resistance is provided by the present invention. The resistive element includes a base layer positioned on top of a metal line. A seed layer of is deposited on top of the base layer. A thin barrier layer of Al is deposited on top of the seed layer and oxidized. A non-magnetic metal layer is then deposited on top of the barrier layer. The base layer and the non-magnetic metal layer form electrodes on either side of the barrier layer. The barrier layer is thin enough that a tunneling current can travel between the electrodes. The resulting resistive element may be constructed with a high resistance and a very small feature size.

### FIELD OF THE INVENTION

This invention generally relates to the field of semiconductor manufacturing. More particularly, the present invention disclosure describes an improved process for manufacturing resistive elements that are smaller than conventional resistors and well suited for integration into modern semiconductor devices.

### BACKGROUND OF THE INVENTION

Resistors are a basic electrical component of almost every integrated circuit. Modern integrated circuits are typically manufactured from semiconductors using a process whereby layers of materials are deposited upon a semiconductor substrate and then patterned by selectively etching away portions of the deposited layers. Typically, resistors are formed by depositing a length of conductive material having a predetermined resistance per unit of length such that the length of the resistor determines its particular resistance value. Thus, to create a resistor having a relatively high resistance, a relatively long length of material must be deposited. However, as integrated circuits increasingly become more complex with more components, they require more and more space on semiconductor substrates to construct. Thus, there is a need in the prior art to produce smaller and smaller resistors. More particularly, there is a need to produce smaller resistors having larger resistance values. Furthermore, the resistors used in integrated circuits are often required to have a resistance value that is within a very narrow range of resistance values. Thus, there is a need in the prior art for a method of producing a resistive element that is smaller than current resistors, yet has a precise resistance value and can be manufactured to have a high resistance value.

### SUMMARY OF THE INVENTION

A preferred embodiment of the present invention is directed toward a method for producing a resistive element. In accordance with the method, a smoothing layer of Ta is deposited over a first electrode. A seed layer of CoFe is then deposited over the smoothing layer and the first electrode. A metal layer is deposited over the seed layer and the metal layer is oxidized in order to form an insulating barrier layer. The barrier layer is constructed so that it is thin enough to allow a tunneling current to flow to a second electrode. The resistance of the resistive element is a function of the thickness of the insulating barrier layer and the area of the resistive element. Accordingly, the resistive element may be patterned and etched such that the resistive element has a predetermined resistance value.

In accordance with another embodiment of the present invention, a method of producing a resistor for use in a semiconductor device is provided. A base layer of TaN is deposited over a metal contact point. A smoothing layer of Ta is then deposited over the base layer. A seed layer of CoFe is deposited over the base layer. A barrier layer of Al less than approximately 2 nanometers thick is deposited over the seed layer. The barrier layer is then oxidized. A non-magnetic metal layer, preferably of Al, is deposited over the barrier layer. Finally, a protective cap layer is deposited over the non-magnetic metal layer. The resistor is then patterned such that the resistor has a desired resistance value. It is also possible to adjust the Al thickness and oxidation conditions to modify the tunnel barrier and obtain the desired resistance value for a given shape.

Yet another embodiment of the present invention is directed toward a resistive element for use in a semiconductor device. The resistive element includes a base layer of TaN positioned over a metal contact. A smoothing layer of Ta is positioned over the base layer. A seed layer is positioned over the smoothing layer and base layer. A barrier layer is positioned over the seed layer. The barrier layer is at least partially oxidized. A non-magnetic metal layer is then positioned over the barrier layer. A protective cap layer is positioned over the non-magnetic metal layer.

Yet another embodiment of the present invention is directed toward a resistor having a top electrode formed from a non-magnetic metal. The bottom electrode includes TaN and the top electrode includes at least one of Al and TaN. A seed layer of CoFe and a thin insulating layer of oxidized Al less than approximately 2 nanometers in thickness are positioned between the bottom electrode and the top electrode. The insulating layer is thin enough to allow a tunneling current to be established between the top electrode and the bottom electrode.

The above described preferred embodiments of the present invention represent a number of improvements upon the prior art. First, unlike prior art resistors, resistors can be constructed in accordance with the present invention to have both a small feature size (because of the vertical structure of the resistor) and a large resistance value. Second, the present invention provides resistors that can reliably be constructed to have a particular resistance value with very little variance in their resistance values. Finally, the resistance value of the resistors can be easily modified by patterning them to have a particular resistance value during an etching process already typically present during the manufacturing process. As an option, the resistance value can also be set by a proper choice of Al thickness and appropriate barrier oxidation. Thus, the present invention represents a substantial improvement upon the prior art.

### BRIEF DESCRIPTION OF THE DRAWINGS

FIG. 1 is a pictorial representation of a resistive stack created in accordance with a preferred embodiment of the present invention;

FIGS. 2(a) and 2(b) are graphs of resistance values for resistive stacks created in accordance with a preferred embodiment of the present invention having a CoFe seed layer;

FIGS. 3(a) and 3(b) are graphs of resistance values for resistive stacks created without a CoFe seed layer; and

FIG. 4 is a flow chart of a method of constructing a resistive element in accordance with a preferred embodiment of the present invention.

### DESCRIPTION OF THE PREFERRED EMBODIMENTS

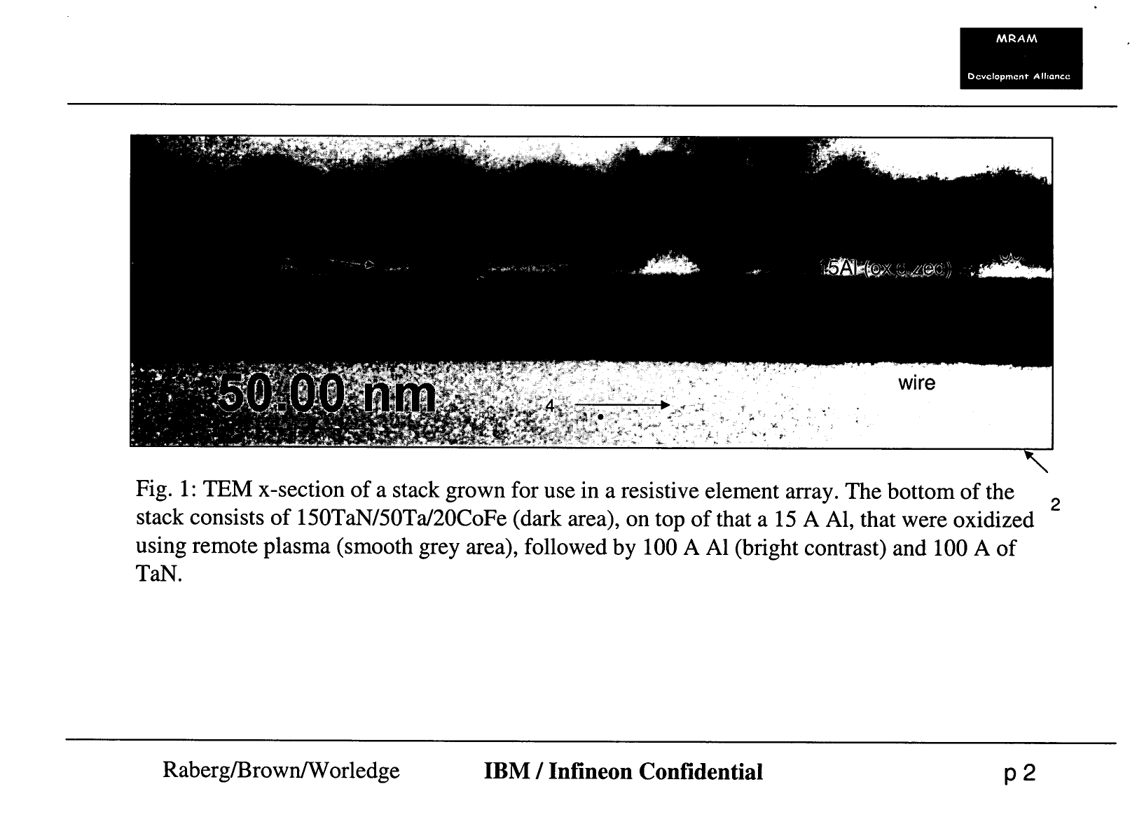

Referring now to FIG. 1, a representation of a resistive stack 2 manufactured in accordance with a preferred embodiment of the present invention is shown. A picture of a resistive stack such as shown in FIG. 1 may be obtained in practice by viewing the resistive stack with a transition electron microscope (TEM). The resistive stack 2 is constructed upon a metal line or layer 4. As discussed in more detail below, the metal line 4 provides one electrical contact point to the resistive stack 2. A Tantalum Nitride (TaN) layer 6 is deposited upon the metal layer 4 to form a base layer 6 of the resistive stack 2. The TaN layer 6 is depicted in FIG. 1 as being 150 Angstroms (A) thick. However, the thickness of the base layer 6 is not critical as long as it does not deviate to the point that the functionality of the resistive stack 2 is substantially affected. In order to provide a smoother surface for deposition of a seed layer, a thin smoothing layer of Tantalum (Ta) 8 is deposited on the surface of the base layer 6. A seed layer 10 of Cobalt Iron (CoFe) is then deposited on top of the smoothing layer 8. The seed layer 10 of CoFe provides a receptive surface for the deposition of the barrier layer 12. The barrier layer 12 preferably consists of a thin layer of Aluminum (Al). Most preferably, the barrier layer 12 is less than 2 nanometers thick. However, as discussed in more detail below, the thickness of the barrier layer 12 will depend upon the desired resistance of the resistive stack with the only requirement being that it is thin enough to allow a tunneling current. Once the barrier layer 12 has been deposited, it is oxidized to create an electrical barrier in the resistive stack. Oxidizing the barrier layer 12 dramatically increases its resistance to the point that the barrier layer 12 essentially functions as an insulator. A non-magnetic layer 14 is then deposited upon the oxidized barrier layer 12. The non-magnetic metal layer 14 is most preferably Al. Finally, a protective layer 16 of TaN is deposited upon the non-magnetic metal layer 14 to protect it from corroding.

The construction set forth in FIG. 1 results in two electrodes, base layer 6 and non-magnetic metal layer 14, that are separated by an insulating barrier, barrier layer 12. The barrier layer 12 is constructed to be thin enough to allow a tunneling current to flow between the electrodes 6 and 14. When in operation, and depending upon the direction of current flow, current collects on the base layer 6, tunnels through the barrier layer 12 and is received by the non-magnetic metal layer 14. The resistance value of the resistive stack 2 depends upon the surface area of the electrodes 6 and 14, the thickness of the barrier layer 12 and the extent of the oxidation of the barrier layer 12. Thus, the resistance of the resistive stack 2 can be made extremely large without a corresponding increase in the size of the resistive stack 2. Therefore, the embodiment shown in FIG. 1 overcomes the prior art size problems associated with constructing a resistor having a large resistance value.

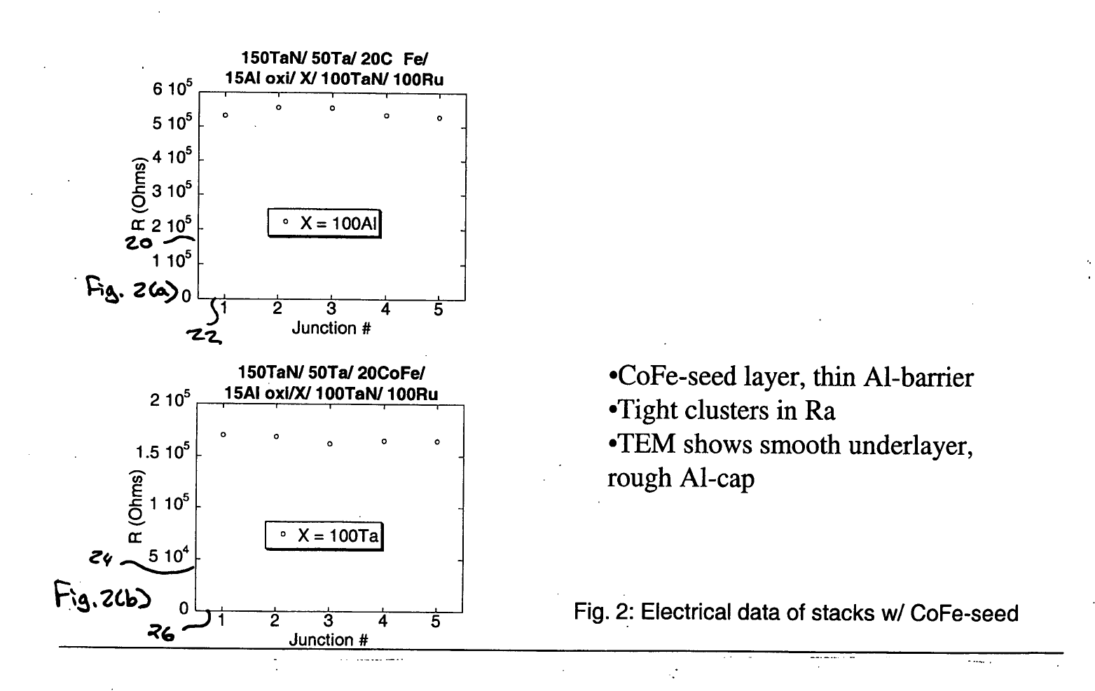

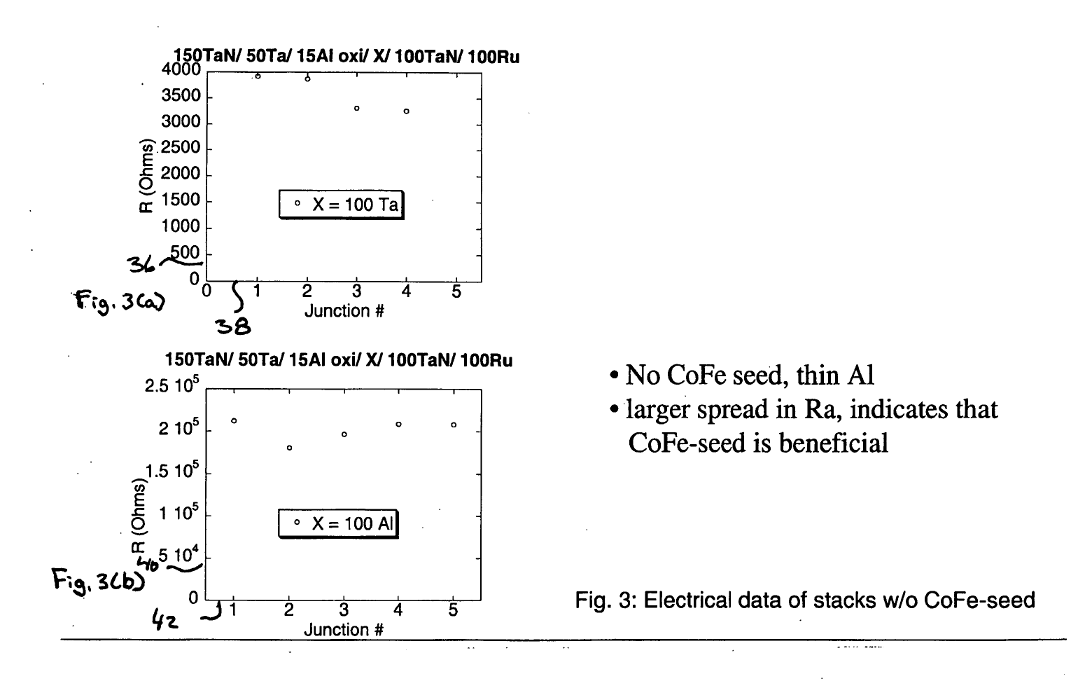

The benefits of using a seed layer 10 of CoFe in conjunction with the resistive structure of FIG. 1 can readily be seen by referring to FIGS. 2(a) and 2(b) and FIGS. 3(a) and 3(b). As depicted in FIGS. 2(a) and 2(b), resistive stacks produced in accordance with preferred embodiments of the present invention have relatively high resistance values in relation to their small size and can be produced within relatively tight tolerances. More particularly, FIG. 2(a) shows the resistance value 20 in ohms for five resistive junctions 22 created from a resistive stack consisting of 150 Å TaN/50 Å Ta/20 Å CoFe/15 Å Al, oxidized/100 Å Al/100 Å TaN/100 Å Ru. All of the resistive junctions 20 have resistance values of approximately 5×10⁵ Ohms. Thus, resistors can be manufactured from the type of resistive stack shown in FIG. 2(a) that have a predictable resistance value within a narrow range of values. In FIG. 2(b), the 100 Å layer of Al in FIG. 2(a) has been replaced with a 100 Å layer of Ta. Although the resistance values 24 of the resistive junctions 26 shown in FIG. 2(b) are different than those of FIG. 2(a), they also display a low variation in resistance values. Thus, resistors can be designed to have a particular resistance value with a low deviation from their desired resistance value in accordance with preferred embodiments of the present invention.

The use of the seed layer in the resistive stacks shown in FIGS. 2(a) and 2(b) produces a more uniform barrier layer and, thus, limits the variance in the resistance values of resistors produced in accordance with preferred embodiments of the present invention. When the deposition of the seed layer is omitted from the manufacturing process, the resistance values of the resistors created varies to a much greater degree. For example, referring now to FIGS. 3(a) and 3(b), graphs of resistance values for resistive stacks created without the use of a seed layer are shown. In FIG. 3(a), the resistance values 36 for a set of resistive junctions 38 similar to those shown in FIG. 2(b), except without the seed layer of CoFe, are shown. In FIG. 3(a), it can be seen that the resistance values 36 vary to a much greater degree than those of the resistive junctions 26 shown in FIG. 2(b). Thus, the seed layer of CoFe significantly diminishes the variance in the resistance values 36. Similarly, the resistive junctions 42 shown in FIG. 3(b) correspond to those of FIG. 2(a) without the seed layer of CoFe. The resistance values 40 of the resistive junctions 42 again display a greater variance in values. Thus, the resistive stacks constructed without a seed layer have a resistance value that is less predictable. Therefore, the use of a seed layer when constructing a resistive stack is a substantial improvement upon the prior art.

The resistive stacks produced in accordance with the present invention are easily scaled to produce resistors having different resistance values. The resistance of the stacks for a given unit area is substantially constant. Thus, the resistance of the resistive stack may be predictably modified by simply modifying the area of the resistive stack. This is preferably accomplished by masking the resistive stack and etching away the unmasked areas to produce a patterned resistive stack having a predetermined area. Since the resistance of a particular resistive stack is primarily dependent upon its area, almost any desired resistance can be achieved by simply altering the dimensions of the resistive stack. Thus, the preferred embodiments of the present invention are well suited for use in semiconductor chips that require resistors having varying resistances.

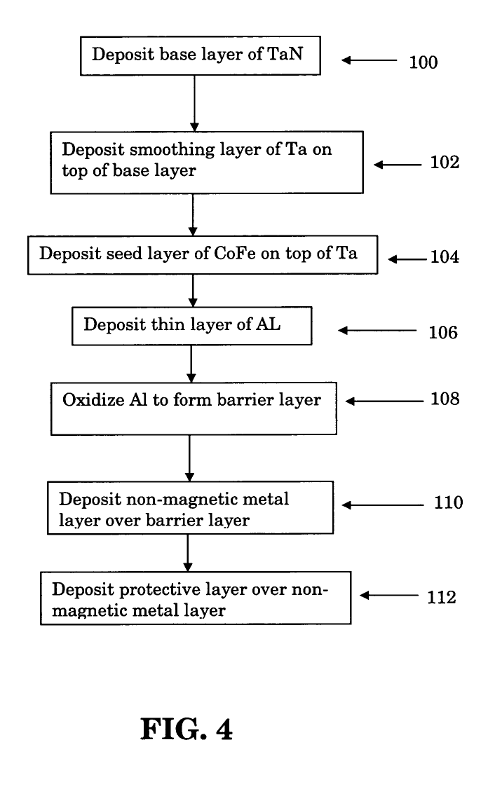

Referring now to FIG. 4, a flow chart of a preferred method of constructing a resistive stack is set forth. The method commences with the deposition of a base layer of TaN on top of a metal line as shown in block 100. A smoothing layer of Ta is then deposited on top of the base layer in block 102. The base layer and smoothing layer create a lower electrode for the resistive stack. In block 104, a seed layer of CoFe is deposited on the smoothing layer of Ta. A thin layer of Al or a similar metal is then deposited on the seed layer in block 106. In block 108, this thin layer of Al is oxidized to produce a barrier layer. The final resistance of the resistive stack will depend upon the thickness of the barrier layer, the oxidation time of the barrier layer and the overall dimensions of the resistive stack. The smoothing layer of Ta provides a good surface for deposition of the seed layer and substantially limits the variance in resistance values that may result from irregularities in the surface of the base layer and, thus, the thickness and uniformity of the barrier layer. A non-magnetic metal layer is deposited over the barrier layer in block 110. This non-magnetic metal layer creates an upper electrode for the resistive stack. Although any suitable non-magnetic metal could be used, Ta and Al have proven to be particularly well suited. Finally, a protective layer is deposited over the non-magnetic metal layer as set forth in block 112.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

1. A method for producing a resistive element comprising the steps of:
depositing a seed layer over a first electrode; and
depositing an insulating barrier layer over the seed layer wherein the barrier layer is thin enough to allow a tunneling current to flow to a second electrode;
wherein the resistive element comprises a resistance that is a function of the thickness of the insulating barrier layer.

2. The method of claim 1 further comprising the step of depositing a smoothing layer of Ta over said first electrode prior to depositing said seed layer.

3. The method of claim 1 further comprising the step of oxidizing the insulating barrier layer.

4. The method of claim 1 further comprising the step of patterning the resistive element such that the resistive element has a predetermined resistance value.

5. The method of claim 1 wherein the step of depositing a seed layer over a first electrode further comprises depositing a seed layer of CoFe.

6. A method of producing a resistor for use in a semiconductor device, said method comprising:
depositing a base layer over a metal contact point;
depositing a seed layer over the base layer;
depositing a barrier layer over the seed layer; and
depositing a non-magnetic metal layer over the barrier layer.

7. The method of claim 6 further comprising the step of depositing a protective cap layer over the non-magnetic metal layer.

8. The method of claim 6 further comprising the step of patterning the resistor such that the resistor has a desired resistance value.

9. The method of claim 6 further comprising the step of oxidizing the barrier layer.

10. The method of claim 9 wherein the barrier layer is oxidized with an oxygen plasma.

11. The method of claim 6 wherein the step of depositing a seed layer over of the base layer comprises depositing a seed layer of CoFe over the base layer.

12. The method of claim 6 wherein the step of depositing a base layer over a metal contact point comprises depositing a base layer containing Ta over a metal contact point.

13. The method of claim 6 wherein the step of depositing a barrier layer over the seed layer comprises depositing a barrier layer of Al over the seed layer.

14. The method of claim 6 wherein the step of depositing a non-magnetic metal layer over the barrier layer comprises depositing a layer of Al over the barrier layer.

15. The method of claim 6 wherein the step of depositing a barrier layer over the seed layer comprises depositing a barrier layer less than approximately 2 nanometers thick over the seed layer.

16. The method of claim 6 further comprising depositing a smoothing layer of Ta over said base layer.

17. A resistive element for use in a semiconductor device, said resistive element comprising:
a base layer positioned over a metal contact;
a seed layer positioned over the base layer;
a barrier layer positioned over the seed layer; and
a non-magnetic metal layer positioned over the barrier layer.

18. The resistive element of claim 17 further comprising a protective cap layer positioned over the non-magnetic metal layer.

19. The resistive element of claim 17 wherein the barrier layer has been at least partially oxidized.

20. The resistive element of claim 17 further comprising a smoothing layer of Ta positioned over said base layer.

21. The resistive element of claim 17 wherein the base layer further comprises TaN.

22. The resistive element of claim 17 wherein said seed layer further comprises CoFe.

23. The resistive element of claim 17 wherein said non-magnetic metal layer further comprises Al.

24. A resistor comprising:
a top electrode formed from one of a magnetic and non-magnetic metal;
a bottom electrode formed of a non-magnetic metal; and
an insulating layer positioned between said bottom electrode and said top electrode wherein said insulating layer is thin enough to allow a tunneling current to be established between said top electrode and said bottom electrode.

25. The resistor of claim 24 wherein said insulating layer further comprises a thin layer of oxidized Al.

26. The resistor of claim 24 wherein said insulating layer further comprises a seed layer of CoFe.

27. The resistor of claim 24 further comprising a smoothing layer of Ta upon which said insulating layer is deposited.

28. The resistor of claim 24 wherein said bottom electrode comprises TaN.

29. The resistor of claim 24 wherein said top electrode further comprises at least one of Al and TaN.

30. The resistor of claim 24 wherein said insulating layer is less than approximately 2 nanometers in thickness.
